(19) United States
(12) Patent Application Publication
(10) Pub. No.: US 2025/0158521 A1
(43) Pub. Date: May 15, 2025

(54) ELECTRONIC CHIP CONNECTED TO AN EXTERNAL VOLTAGE

(71) Applicant: STMicroelectronics International N.V., Geneva (CH)

(72) Inventor: Lionel CIMAZ, Pleumeleuc (FR)

(73) Assignee: STMicroelectronics International N.V., Geneva (CH)

(21) Appl. No.: 18/941,121

(22) Filed: Nov. 8, 2024

(30) Foreign Application Priority Data
Nov. 9, 2023 (FR) 2312255

(51) Int. Cl. H02M 3/155; H02H 9/04; H03K 17/687

(52) U.S. Cl. CPC H02M 3/155; H02H 9/046; H03K 17/687

(57) ABSTRACT

An integrated circuit chip includes a first pad coupled to an external power supply voltage by a conductive wire; a PMOS transistor coupling the first pad to an internal node; a second pad coupled to an external reference voltage by another conductive wire; and a capacitor coupling said first and second pads. A sensing circuit detects an increase in a drain-source resistance of the transistor. A control circuit supplies, during each switching of the transistor to the off state, a first current to the gate of the transistor until the sensing circuit detects the increase in the drain-source resistance, then supplies a second current lower than the first current.

### PRIORITY CLAIM

This application claims the priority benefit of French Application for Patent No. 2312255, filed on Nov. 9, 2023, the content of which is hereby incorporated by reference in its entirety to the maximum extent allowable by law.

### TECHNICAL FIELD

The present disclosure generally concerns integrated electronic circuits and, more particularly, integrated circuit chips connected to a power supply voltage external to the chip (“off-chip”) by a conductive wire, that is, by wire bonding.

### BACKGROUND

Many known integrated circuit chips comprise a connection pad configured to be connected to a power supply voltage external to the chip via a conductive wire and another connection pad configured to be connected to a reference voltage by another conductive wire.

Some of these known chips comprise a PMOS transistor used as a switch, for example as a high-side switch of a DC-DC switched-mode power supply (SMPS) converter. This PMOS transistor switch couples an internal node of the chip, itself coupled to a load, to the connection pad, which is connected to the power supply voltage. Further, these chips comprise a decoupling capacitor coupling the two connection pads to each other.

These known chips comprising a PMOS transistor switch such as described hereabove have various disadvantages.

There exists a need to overcome all or part of the disadvantages of integrated circuit chips such as described hereabove.

For example, there exists a need, during the switching to the off state of the PMOS transistor switch of these chips, to limit, or even to avoid, voltage oscillations on the source of the PMOS transistor switch resulting from the parasitic inductor of the conductive wire coupling the power supply voltage to the corresponding connection pad of the chip.

### SUMMARY

An embodiment provides an integrated circuit chip comprising: a first connection pad intended to be coupled to an external power supply voltage by a first conductive wire; a second connection pad intended to be coupled to an external reference voltage by a second conductive wire; a PMOS transistor coupling the first connection pad to an internal node of the integrated circuit chip configured to be connected to a load; a decoupling capacitor coupling the first and second connection pads together; a first detection circuit configured to detect an increase, for example above a first threshold, in a drain-source resistance of the PMOS transistor; and a first control circuit configured, during each switching of the PMOS transistor to the off state, to supply a first current to the gate of the PMOS transistor until the first detection circuit detects an increase in the drain-source resistance, and then to supply a second current to the gate of the PMOS transistor that is lower than the first current.

According to an embodiment, the integrated circuit chip further comprises a diode coupling the internal node to the second connection pad, wherein the anode of the diode is on the side of the second connection pad.

According to an embodiment, the internal node is coupled, preferably connected, to a third connection pad of the integrated circuit chip, the third connection pad being intended to be connected to an external inductor by a third conductive wire, the external inductor forming part of the load.

According to an embodiment, the integrated circuit chip further comprises a protection circuit against electrostatic discharge coupling the first and second connection pads together.

According to an embodiment, the first detection circuit comprises a comparator configured to compare the source voltage of the PMOS transistor with the drain voltage of the PMOS transistor increased by a threshold voltage of the first detection circuit, and to provide a binary signal indicating a result of the comparison.

According to an embodiment, the integrated circuit chip further comprises a second control circuit configured to supply a first binary signal to the first control circuit, a first binary state of the first binary signal controlling the off state of the PMOS transistor and a second binary state of the first binary signal controlling an on state of the PMOS transistor.

According to an embodiment, the integrated circuit chip further comprises: an NMOS transistor coupling the internal node to the second connection pad; and a third control circuit configured to control the NMOS transistor, the second control circuit being configured to supply a second binary signal to the third control circuit, a first binary state of the second binary signal controlling the off state of the NMOS transistor and a second binary state of the second binary signal controlling an on state of the NMOS transistor.

According to an embodiment: the integrated circuit chip further comprises a second detection circuit configured to detect when a voltage of the internal node is close to a null value, for example by comparing said voltage with a second threshold; and the second control circuit is configured to switch the second signal to its second binary state when the second detection circuit detects that the voltage of the internal node is close to the null value.

According to an embodiment, the second detection circuit comprises a comparator configured to compare the voltage of the internal node with the voltage of the second connection pad increased by a threshold voltage of the second detection circuit, and to provide a binary signal indicating a result of the comparison.

According to an embodiment: the integrated circuit chip further comprises a third detection circuit configured to detect that the PMOS transistor is in the off state; and the second control circuit is configured to switch the second binary signal to its second binary state as soon as the second detection circuit detects that the voltage of the internal node is close to zero or the third detection circuit detects that the PMOS transistor is in the off state.

According to an embodiment, the first control circuit is configured to supply the first current if the first detection circuit does not detect an increase in drain-source resistance and the third detection circuit detects that the PMOS transistor is in the off state, and to supply the second current otherwise.

According to an embodiment: the integrated circuit chip further comprises a third detection circuit configured to detect that the PMOS transistor is in the off state; and the first control circuit is configured to supply the first current if the first detection circuit does not detect an increase in drain-source resistance and the third detection circuit detects that the PMOS transistor is in the off state, and to supply the second current otherwise.

According to an embodiment, the third detection circuit comprises: an additional PMOS transistor mirror connected with the PMOS transistor and having its drain coupled to the second connection pad by a resistor or constant current source; and a comparator configured to compare the source voltage of the additional PMOS transistor to a threshold and to provide a binary signal indicating the result of the comparison.

According to an embodiment, the PMOS transistor is a high-side transistor of a DC-DC switched mode power supply.

Another embodiment provides an electronic device, wherein the device comprises: the above-described integrated circuit chip; a source of the supply voltage disposed outside the integrated circuit chip and coupled to the first connection pad of the integrated circuit chip by the first conductive wire; and a source of the reference voltage disposed outside the integrated circuit chip and coupled to the second connection pad of the integrated circuit chip by the second conductive wire.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 shows, at least partly in the form of blocks, an example of an electronic device;

FIG. 2 shows, at least partly in the form of blocks, an example of an electronic device;

FIG. 3 shows, at least partly in the form of blocks, an example of an alternative embodiment of the electronic device of FIG. 2;

FIG. 4 shows, at least at least partly in the form of blocks, an example of another alternative embodiment of the electronic device of FIG. 2;

FIG. 5 shows an example of embodiment of a circuit of the device of FIGS. 2, 3, and 4;

FIG. 6 shows an example of embodiment of a circuit of the device of FIGS. 3 and 4; and

FIG. 7 shows an example of embodiment of a circuit of the device of FIG. 4.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

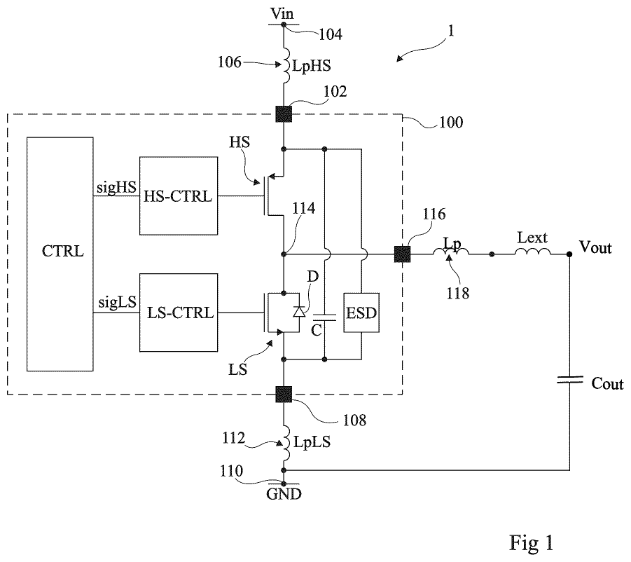

FIG. 1 shows, at least partly in the form of blocks, an example of an electronic device or system 1.

Device 1 comprises an integrated circuit chip 100, delimited in dotted lines in FIG. 1.

Chip 100 comprises a connection pad 102. Pad 102, which may also be referred to as a bonding pad of the chip 200, is intended to be connected to a power supply voltage Vin, voltage Vin being, for example, a Direct Current (DC) voltage and being, for example, positive with respect to a DC reference voltage GND, for example the ground. More particularly, pad 102 is intended to be connected to power supply voltage Vin, that is, to a pad 104, which may also be referred to as a package lead, of device 1 which is external to chip 100 and which is at voltage Vin, by a conductive wire 106 represented in FIG. 1 by its parasitic inductance LpHS.

Chip 100 further comprises a connection pad 108. Pad 108, which may also be referred to as a bonding pad of the chip 200, is intended to be connected to reference voltage GND. More particularly, pad 108 is intended to be connected to voltage GND, that is, to a pad 110, which may also be referred to as a package lead, of device 1 which is external to chip 100 and which is at voltage GND, by a conductive wire 112 represented in FIG. 1 by its parasitic inductance LpLS.

Chip 100 further comprises a PMOS transistor (P-type Metal Oxide Semiconductor transistor), designated with reference HS in FIG. 1. Transistor HS couples pad 102 to an internal node 114 of chip 100. For example, the source of transistor HS is coupled, preferably connected, to pad 102, and the drain of transistor HS is coupled, preferably connected, to node 114. Transistor HS is used (controlled) as a switch.

Node 114 is intended to be coupled to a load. In the example of FIG. 1, node 114 is coupled, preferably connected, to a connection pad 116 of the chip, pad 116 being intended to be connected to all or part of the load, by a conductive wire 118 represented by its parasitic inductance Lp in FIG. 1. More particularly, in the example of FIG. 1, the load comprises an inductor Lext external to chip 100, inductor Lext having a first terminal connected to wire 118 to be coupled to node 114, and a second terminal coupled to voltage GND, that is, to pad 110, by a load to be powered comprising a capacitive element Cout (only the capacitive element Cout of the load to be powered is shown in FIG. 1). In this example, where device 1 is a switched-mode DC-DC converter, capacitive element Cout enables to maintain, once it has been charged, a voltage Vout on the node of connection of inductor Lext to capacitor Cout.

The chip also comprises a capacitive element C coupling pads 102 and 108 to each other. For example, capacitive element C has a first terminal or electrode coupled, preferably connected, to pad 102, and a second terminal or electrode coupled, preferably connected, to pad 108.

Node 114 is further coupled to pad 108 by a diode D of chip 100, diode D having its anode on the side of (i.e., facing) pad 108 and its cathode on the side of (i.e., facing) node 114. For example, diode D has its anode coupled, preferably connected, to pad 108, and its cathode coupled, preferably connected, to node 114.

In the example of FIG. 1, switch HS is the high-side switch of a switched-mode DC-DC converter, the converter being a buck converter. Diode D corresponds to the free-wheel diode of the converter.

In the example of FIG. 1 where switch HS forms part of a switched-mode DC-DC converter, chip 100 further comprises an NMOS transistor (N-type Metal Oxide Semiconductor transistor), designated with reference LS in FIG. 1. Transistor LS couples node 114 to pad 108. For example, the source of transistor LS is coupled, preferably connected, to pad 108, and the drain of transistor LS is coupled, preferably connected, to node 114. Transistor LS is used (controlled) as a switch. As an example, diode D corresponds to the body diode of transistor LS. As another example, diode D is connected in parallel with transistor LS. As another example, transistor LS may be omitted.

Optionally, chip 100 comprises an electrostatic discharge protection circuit ESD, coupling pads 102 and 108 together. Circuit ESD is configured to be conductive, that is, to allow the flowing of a current from pad 102 to pad 108, when the voltage difference between pads 102 and 108 exceeds a threshold, and non-conductive otherwise.

Chip 100 comprises a control circuit HS-CTRL for controlling transistor HS. Circuit HS-CTRL controls the gate of transistor HS so as to control the conductive or non-conductive state of transistor HS. For example, when circuit HS-CTRL controls a switching from the conductive state to the non-conductive state of transistor HS, this circuit HS-CTRL delivers a constant current to the gate of transistor HS, which discharges until the gate-source voltage of transistor HS is lower than the turn-on threshold of transistor HS and the latter is in the non-conductive state, thus preventing the flowing of a current from pad 102 to node 114. Conversely, when circuit HS-CTRL controls a switching from the non-conductive to the conductive state of transistor HS, circuit HS-CTRL draws a constant current from the gate of transistor HS, which charges until the gate-source voltage of transistor HS is higher than the turn-on threshold of transistor HS and the latter is in the conductive state, thus allowing the flowing of a current from pad 102 to node 114.

As an example, circuit HS-CTRL receives a binary signal sigHS indicating by its first binary state that circuit HS-CTRL is to control transistor HS to the non-conductive state, and by its second binary state that circuit HS-CTRL is to control transistor HS to the conductive state.

As an example, signal sigHIS is delivered by a switching control circuit CTRL forming part of chip 100.

In examples where chip 100 comprises transistor LS, chip 100 comprises a control circuit LS-CTRL for controlling transistor LS. Circuit LS-CTRL controls the gate of transistor LS so as to control the conductive or non-conductive state of transistor LS. For example, when circuit LS-CTRL controls a switching from the conductive state to the non-conductive state of transistor LS, this circuit LS-CTRL draws a constant current from the gate of transistor LS, which discharges until the gate-source voltage of transistor LS is lower than the turn-on threshold of transistor LS and the latter is in the non-conductive state, thus preventing the flowing of current from pad 108 to node 114. Conversely, when circuit LS-CTRL controls a switching from the non-conductive state to the conductive state of transistor LS, this circuit LS-CTRL supplies a constant current to the gate of transistor LS, which charges until the gate-source voltage of transistor LS is higher than the turn-on threshold of transistor LS and the latter is in the conductive state, thus allowing the flowing of a current from pad 108 to node 114.

As an example, circuit LS-CTRL receives a binary signal sigLS indicating by its first binary state that circuit LS-CTRL is to control transistor LS to the non-conductive state, and by its second binary state that circuit LS-CTRL is to control transistor LS in the conductive state.

As an example, signal sigLH is delivered by switching control circuit CTRL.

In the device 1 of FIG. 1, when switch HS is on and switch LS, if present, is off, a current flows from pad 104 to pad 110, successively via wire 106, transistor HS, wire 118, inductor Lext, and the load Cout to be powered.

When transistor HS is then switched to the non-conductive state, this current can no longer flow through transistor HS. However, since the current in an inductor has no discontinuity, the current that used to flow through parasitic inductor LpHS looks for a conductive path towards pad 110. This current then flows all the way to pad 108 via capacitive element C, then to node 114 via diode D or transistor LS if the latter is conducting, then to pad 110 via wire 118, inductor Lext, and load Cout to be powered. Indeed, this current cannot flow all the way to pad 110 via wire 112 due to the fact that, at the time of the switching to the non-conductive state of transistor HS, the current in inductor LpLS is zero and the current in inductor LpLS can exhibit no discontinuity.

In this case, inductor LpHS, capacitive element C, and inductor Lp form a resonant circuit LC between pad 104 and inductor Lext. Further, voltage Vin is constant and the voltage on pad 116 varies little due to the fact that, in practice, inductance Lext has values much greater, for example at least 10 times greater, than that of parasitic inductance LpHS and that of parasitic inductance Lp. This results in oscillations in the voltage on pad 102.

These oscillations reach maximum values capable of damaging or even destroying transistor HS and the other PMOS transistors (not shown) of chip 100 which are connected to pad 102.

When it is present, circuit ESD is triggered by the increase in the voltage between pads 102 and 108 and short-circuits capacitive element C, which enables to prevent oscillations. However, this ESD device is not designed to trigger at each switching to the non-conductive state of transistor HS, and will thus age faster.

Further, if circuit ESD is implemented based on components of Silicon Controlled Rectifier (SCR) type, circuit ESD may, once triggered, remain on as long as the voltage between pads 102 and 108 does not become zero, and thus prevent the correct operation of chip 100, for example of the switched-mode converter comprising transistor HS.

As an example, for a voltage Vin equal to 3 V, wires 106, 112, and 118, each having a 4-nH parasitic inductance and a 50-mOhms parasitic resistance, a 10-pF capacitance C, and a 0.46-A current in parasitic inductor LpHS at the time when switch HS is switched to the off state, the voltage on pad 102, substantially equal to 3 V before the switching of switch HS, has a peak at 5.5 V just 1.6 ns after the switching.

Increasing the value of capacitance C enables to decrease the oscillation amplitude. However, increasing the value of capacitance C to make the amplitude of the oscillations acceptable for the MOS transistors connected to pad 102 results in a significant increase in the surface area of chip 100, which is not desirable. Taking the above numerical example, increasing the value of capacitance C from 10 pF to 1,000 pF decreases the voltage peak on pad 102 to 4.06 V, but the surface area of capacitive element C is then 100 times greater, and becomes of the same order of magnitude as the surface area occupied by the converter on chip 100.

Decreasing the value of parasitic inductance LpHS and that of parasitic inductance Lp enables to decrease the oscillation amplitude. However, it is not always possible to decrease the value of these parasitic inductances. This is for example the case when chip 100 is manufactured by a first entity, and assembled by a second entity on a support to which the chip 100 is connected by wires 106, 112, and 118.

In practice, during the switching of a PMOS transistor to the non-conductive state, there is a first phase during which the transistor gate discharges and the transistor gate-source voltage decreases (in absolute value) with a slope proportional to the current supplied to the transistor gate by its control circuit, without for the drain-source resistance of the transistor to change. Then, the gate-source voltage of the transistor reaches a plateau corresponding to a second phase during which the carriers which had accumulated under the transistor gate are removed without for the drain-source resistance to significantly change, the duration of the plateau being determined by the current supplied to the gate of the transistor by its control circuit. Finally, at the end of this plateau, during a third phase, the gate-source voltage of the transistor decreases again (in absolute value) with a slope proportional to the current supplied to the transistor gate by its control circuit, and the resistance between the source and the drain of the transistor increases with the variation of the gate-source voltage, until this resistance is sufficiently high for the transistor to be in the non-conductive state. The transistor switching time is then equal to the total time corresponding to the succession of the first, second, and third phases, and the transistor remains conductive for ⅘ of the switching time.

Although this is not detailed, the PMOS transistor has a symmetrical behavior during a switching to the conductive state, where the transistor remains non-conductive for ⅘ of the time of switching to the conductive state, and NMOS transistors also have a similar behavior.

By decreasing the current supplied to the gate of transistor HS by the circuit during the first, second, and third successive phases of the switching of transistor HS to the non-conductive state, this would result in an increase in the duration of each of these three phases, and thus, during the third phase, in a corresponding decrease of the rate at which the drain-source resistance of transistor HS increases. This could make it possible to discharge, during the third phase, inductor LpHS so that the current therein is zero when transistor HS effectively switches to the non-conductive state. However, this would also increase the duration of the first and second phases, and thus the total duration of the switching of transistor HS to the non-conductive state, which is not desirable. Indeed, in many applications, it is generally desired to decrease the total duration of each switching between the non-conductive and conductive states of the switches.

For example, in a switched-mode DC-DC converter, it is desirable for the switching time of each of switches HS and LS to amount to less than 1/20 of the total duration of an operating cycle of a converter. For a DC-DC converter having a 5-MHz operating frequency, that is, a 200-ns operating cycle time, this means that the switching time of each of switches LS and HS must be 10 ns, and that the duration of the third phases described above must be 2 ns. Returning to the previous numerical example, to decrease the amplitude of the oscillations on pad 102 to acceptable values, the duration of each third phase would have to be, for example, greater than or equal to 25 times L·I/Vin, with L the inductance value of parasitic inductor LpHS, I the 0.4-A current in inductor LpHS at the time of switching, and Vin equal to 3.3 V. This results in a duration the third phase of at least 13 ns, and thus in a total switching time of at least 65 ns, which is not compatible with a 10-ns operating cycle time.

It is here provided, during the switching of transistor HS to the non-conductive state, to supply it with a first current during the first and second switching phases, and with a second current during the third switching phase. By providing for the first current to be higher than the second current, this enables the first and second phases of the switching to be faster than the third phase, which will be slower. It is then possible to maintain a total time for the switching to the non-conductive state compatible with a given operating frequency, by ensuring a complete discharge of inductor LpHS at the time when transistor HS effectively switches to the non-conductive state, which enables to decrease, or even to suppress, oscillations on pad 102 without having to modify the values of the parasitic inductances and the value of capacitance C.

As an example, the third phase may then be sufficiently slow for inductor LpHS to fully discharge before transistor HS effectively switches to the non-conductive state, while keeping first and second phases sufficiently fast for the total duration of the switching, that is, the total duration of the first, second, and third phases, to be compatible with a target operating frequency of the DC-DC converter.

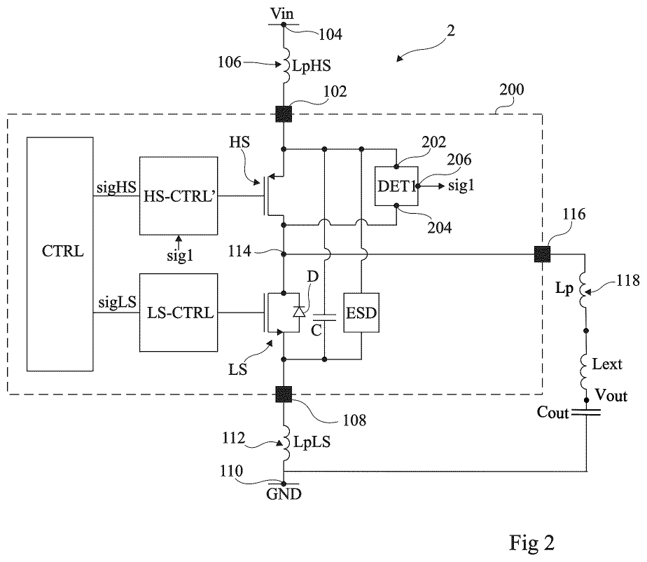

FIG. 2 shows, at least partly in the form of blocks, an example of embodiment of an electronic device 2.

Device 2 differs from the device 1 of FIG. 1 in that chip 100 is replaced with a chip 200.

Chip 200 is similar to chip 100, and only the differences between these two chips are here highlighted. Thus, unless specified otherwise, all that has been indicated for chip 100 applies to chip 200.

In particular, chip 200 differs from chip 100 in that: circuit HS-CTRL is replaced with a control circuit HS-CTRL′; and chip 200 comprises a detection circuit DET1.

Circuit DET1 is configured to detect when the drain-source resistance, for example called on-state resistance (Rds_on), of transistor HS increases.

Preferably, circuit DET1 is configured to detect when the drain-source resistance of transistor HS exceeds a threshold value.

As an example, this threshold value is determined so that, during a switching to the off state of transistor HS, the drain-source resistance of transistor HS becomes greater than this threshold value when the transistor transits from the second phase of the switching (plateau) to the third phase of the switching (increase of the on-state resistance).

As an example, circuit DET1 delivers a binary signal sig1 indicating by a first binary state that the drain-source resistance of transistor HS is not increasing, that is, for example, that this drain-source resistance is lower than the threshold value and corresponds to the conductive state of transistor HS, and by a second binary state that the drain-source resistance of transistor HS is increasing, that is, for example, that this drain-source resistance is greater than the threshold value and that the transistor is in the third phase of its switching to the non-conductive state. Signal sig1 is, for example, available on an output 206 of circuit DET1.

As an example, circuit DET1 comprises an input 202 connected to the source of transistor HS and an input 204 connected to the drain of transistor HS.

As an example, circuit DET1 is configured to compare the drain-source voltage of transistor HS (which is indicative of the drain-source resistance) with a threshold, the drain-source voltage of transistor HS being greater than the threshold when the drain-source resistance of transistor HS is greater than the threshold value indicating that transistor HS is in the third phase of a switching to the non-conductive state, and the drain-source voltage of transistor HS being lower than the threshold when the drain-source resistance of transistor HS is lower than the threshold value indicating that transistor HS is conducting and in the second or first phase of a switching to the non-conductive state.

The circuit HS-CTRL′ for controlling transistor HS is, like circuit HS-CTRL, configured to control the gate of transistor HS so as to control the conductive or non-conductive state of transistor HS. As an example, circuit HS-CTRL′ receives a binary signal sigHS indicating by its first binary state that circuit HS-CTRL is to control transistor HS to the non-conductive state, and by its second binary state that circuit HS-CTRL is to control transistor HS to the conductive state. As an example, signal sigHS is delivered by a switching control circuit CTRL forming part of chip 200.

However, as compared with circuit HS-CTRL, circuit HS-CTRL′ receives from circuit DET1 an indication that the drain-source resistance of transistor HS is or not increasing. For example, circuit HS-CTRL′ receives signal sig1.

In this example of embodiment, circuit HS-CTRL′ is configured, at each switching to the non-conductive state of transistor HS, to supply a first current to the gate of transistor HS until circuit DET1 detects an increase in the drain-source resistance of transistor HS, and then to supply a second current lower than the first current. In other words, circuit HS-CTRL′ is configured, during each switching of transistor HS to the non-conductive state, to supply the first current during the first and second phases of the switching when transistor HS is still conducting, and then to supply the second current during the third phase when the drain-source resistance of transistor HS increases until the transistor is effectively in the non-conductive state.

As an example, the above-described operation of circuit HS-CTRL′ corresponds to the operation of circuit HS-CTRL′ when signal sigHS switches to its first binary state, until signal sigHS switches back to its second binary state.

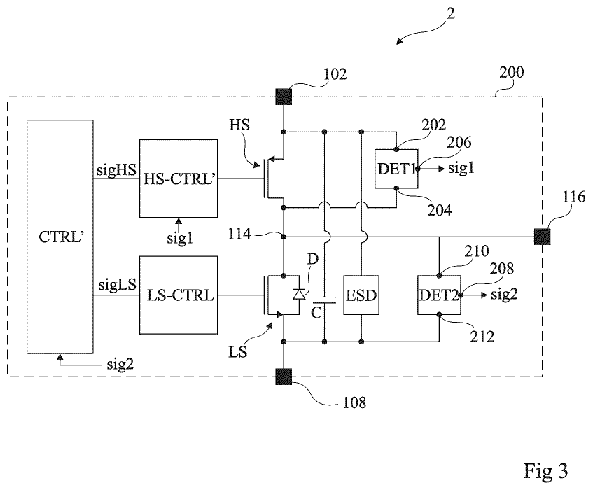

FIG. 3 shows, at least partly in the form of blocks, an example of an alternative embodiment of the device 2 of FIG. 2.

Only the differences between the device 2 of FIG. 2 and the device 2 of FIG. 3 are here highlighted. Thus, unless specified otherwise, all that has been indicated for the device 2 of FIG. 2 applies to the device 2 of FIG. 3. In FIG. 3, only the chip 200 of device 2 is shown.

In particular, the device 2 of FIG. 3 differs from that of FIG. 2 in that: chip 200 comprises a detection circuit DET2; and circuit CTRL is replaced therein by a switching control circuit CTRL′.

Further, in this variant, chip 200 comprises transistor LS, and transistors HS and LS are controlled so that transistors HS and LS and inductor Lext altogether implement a switched-mode DC-DC converter, operating in pulse width modulation (PWM) and/or in pulse frequency modulation (PFM). Preferably, converter 2 is of buck type.

In usual converters of the type described in relation with FIG. 1, during a switching of transistor HS to the non-conductive state, transistor LS is only switched to the conductive state after the switching to the non-conductive state of transistor HS, that is, after the end of the third phase of this switching.

In the case of the chips 200 described herein, the increase in the drain-source resistance of transistor HS during the third phase of each switching to the conductive state of this HS transistor is slower due to the second current lower than the first current to enable to discharge inductor LpHS before the end of the switching to the non-conductive state. As a result, although transistor HS is not effectively in the non-conductive state yet and is still in the third phase of the switching, the drain-source resistance of transistor HS and the current which flows between the source and drain of transistor HS may have values such that the voltage at node 114 becomes sufficiently negative, for example lower than or equal to −0.7 V, for diode D to start conducting, which causes unwanted losses in diode D.

To avoid the unwanted turning-on of diode D, circuit DET2 is configured to detect when the voltage at node 114 is close to the value of reference voltage GND but still higher than the latter, that is, to detect when the voltage at node 114 is still positive but close to a zero value.

Preferably, circuit DET2 is configured to detect when voltage 114 becomes lower than a threshold voltage. In other words, when the voltage at node 114 decreases during a switching to the non-conductive state of transistor HS, it is considered as being close to a zero value if it becomes lower than this threshold voltage. As an example, this threshold voltage of circuit DET2 is in the range from Vin/10 to 0 V.

As an example, circuit DET2 delivers a binary signal sig2 indicating by a first binary state that the voltage of node 114 is close to zero, that is, for example, that this voltage is lower than the threshold voltage, and by a second binary state that the voltage of node 114 is distant from the zero value, that is, for example, that this voltage is higher than the threshold voltage. Signal sig2 is available, for example, on an output 208 of circuit DET2.

As an example, circuit DET2 comprises an input 210 connected to node 114, and an input 212 connected to pad 108.

Further, it is provided, when circuit DET2 indicates that the voltage at node 114 is close to a zero value, to switch transistor LS to the conductive state. Thus, transistor LS is switched to the conductive state before the voltage at node 114 becomes negative and reaches values likely to turn on diode D.

For this purpose, circuit CTRL′ is similar to circuit CTRL but differs from the latter in that: circuit CTRL′ receives from circuit DET2 the indication that the voltage of node 114 is or is not close to a zero value, for example, circuit CTRL′ receives signal sig2; and circuit CTRL′ controls a switching of transistor LS to the conductive state, that is, circuit CTRL′ switches signal sigLS to its second binary state, as soon as circuit DET2 detects that the voltage at node 114 is close to a zero value, although the switching to the non-conductive state of transistor HS may not be complete.

Thus, transistor LS will be conductive before the voltage at node 114 reaches values likely to turn on diode D, and the current will flow through conducting transistor LS rather than through the more resistive diode D, which limits losses.

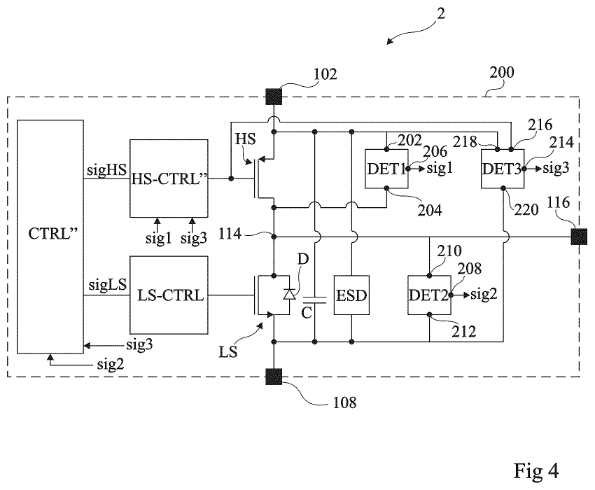

FIG. 4 shows, at least partly in the form of blocks, an example of another alternative embodiment of the electronic device 2 of FIG. 2.

The electronic device 2 of FIG. 4 has many elements in common with that of FIG. 3, and only the differences between these two devices are here highlighted. Thus, unless specified otherwise, all that has been indicated for the device 2 of FIG. 3 applies to the device 2 of FIG. 4. In FIG. 4, only the chip 200 of device 2 is shown.

In particular, the device 2 of FIG. 4 differs from that of FIG. 3 in that: chip 200 comprises a detection circuit DET3; and circuit CTRL′ is replaced with a switching control circuit CTRL″.

In the device 2 of FIG. 3, circuit CTRL′ switches transistor LS to the conductive state after a detection, by circuit DET2, that the voltage at node 114 is close to the zero value.

However, this operation is acceptable if, during each switching of transistor HS to the non-conductive state, the voltage at node 114 decreases sufficiently to become close to the zero value and to trigger the switching to the conductive state of transistor LS. As an example, this is not the case in certain applications where the current flowing through transistor HS during its switching to the non-conductive state is too low and/or a parasitic capacitance on node 114 is too high for the voltage at node 114 to become close to the zero value.

For these applications, it is then provided to use the device 2 of FIG. 4, in which, as compared with the device 2 of FIG. 3: circuit CTRL′ is replaced with a switching control circuit CTRL″; and chip 200 further comprises a detection circuit DET3.

Circuit DET3 is configured to detect when transistor HS is in the non-conductive state.

Preferably, circuit DET3 is configured to detect when the current in transistor HS becomes lower than a threshold, transistor HS being considered to be in the non-conductive state when the current in transistor HS is lower than this threshold.

As an example, circuit DET3 delivers a binary signal sig3 indicating by a first binary state that transistor HS is in the conductive state, that is, for example, that the current flowing through transistor HS is higher than the above-mentioned threshold, and by a second binary state that transistor HS is in the non-conductive state, that is, for example, that the current flowing through transistor HS is lower than this threshold. Signal sig3 is available, for example, on an output 214 of circuit DET3.

As an example, circuit DET3 comprises an input 216 connected to the gate of transistor HS, an input 218 connected to the source of transistor HS, and an input 220 connected to pad 108.

Control circuit CTRL″ is, in this example, configured like circuit CTRL′ to control a switching to the conductive state of transistor LS as soon as circuit DET2 detects, after or during a switching to the conductive state of transistor HS, that the voltage of node 114 is close to the zero value.

However, as compared with circuit CTLR′, circuit CTRL″ further receives from circuit DET3 an indication that transistor HS is or not non-conducting. For example, circuit CTRL″ receives signal sig3.

Circuit CTRL″ is then configured to control a switching to the conductive state of transistor LS as soon as circuit DET3 detects, after or during a switching to the non-conductive state of transistor HS, that transistor HS is effectively in the non-conductive state. In other words, in this example, as soon as circuit CTRL″ receives an indication that the voltage of node 114 is close to the zero value, or that transistor HS is indeed in the non-conductive state, circuit CTRL″ controls the switching of transistor LS to the conductive state.

Thus, if after a switching to the non-conductive state of transistor HS, the voltage at node 114 does not become sufficiently close to the zero value for this to trigger the switching to the conductive state of transistor LS, this switching to the non-conductive state of transistor LS will be triggered anyhow as soon as transistor HS will effectively be in the non-conductive state.

In the example of FIG. 4, circuit CTRL″ switches transistor LS to the conductive state as soon as it receives the indication that the voltage of node 114 is close to the zero value, or the indication that transistor HS is non-conducting.

In other examples, chip 200 does not comprise circuit DET2 and circuit CTRL″ is configured to control the switching to the conductive state of transistor LS only when it receives the indication that transistor HS is in the non-conductive state. In these other examples, it is then possible for diode D to turn on before transistor LS is conducting, and losses will then be higher than in the example of FIG. 3 or 4.

Optionally, as shown in FIG. 4, when chip 200 comprises circuit DET3, circuit HS-CTRL′ may be replaced with a control circuit HS-CTRL″ which receives not only the indication that the drain-source resistance of transistor HS is greater than a threshold value, that is, for example, signal sig1, but also the indication that transistor HS is in the non-conductive state or not, that is, for example, signal sig3.

In this case, circuit HS-CTRL″ is configured to supply the first current as long as circuit DET3 detects that transistor HS is non-conducting or that circuit DET1 detects no increase of the drain-source resistance of transistor HS. Thus, during each switching of transistor HS to the non-conductive state, circuit HS-CTRL″ supplies the first current until circuit DET1 detects an increase in the drain-source resistance of transistor HS, even though transistor HS is not non-conducting yet. From this time onwards, circuit HS-CTRL″ supplies the second current until circuit DET3 detects that transistor HS is in the non-conductive state. From this time onwards, circuit HS-CTRL″ supplies the first current.

As a result, when transistor HS is non-conducting, the voltage on its gate will be less sensitive to variations of the voltage of node 114, which propagate to the gate of transistor HS by capacitive coupling, than in the case where the transistor gate would still be receiving the second, lower, current. This avoids possible settings to the conductive state of transistor HS which would not have been desired.

As an example, the above-described operation of circuit HS-CTRL″ corresponds to the operation of circuit HS-CTRL″ when signal sigHS switches to its first binary state, until signal sigHS switches back to its second binary state.

In still other examples, a chip 200 comprising circuits DET1, DET2, DET3, CTRL′, and HS-CTRL″, or also a chip comprising circuits DET1, DET2, DET3, CTRL″, and HS-CTRL′, may be provided.

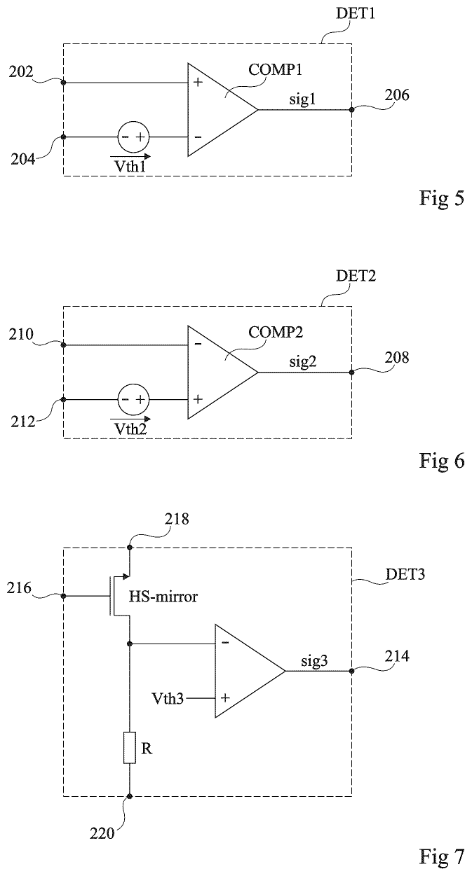

FIG. 5 shows a detailed example embodiment of the circuit DET1 of the device 2 of FIGS. 2, 3, and 4.

In this example, circuit DET1 comprises a comparator COMP1. Comparator COMP1 is configured to compare the source voltage of transistor HS with a voltage equal to the sum of the drain voltage of transistor HS and of a threshold voltage Vth1. In other words, comparator COMP1 is configured to compare the source voltage of transistor HS with the drain voltage of transistor HS increased by voltage Vth1. Still in other words, comparator COMP1 is configured to compare the drain-source voltage of transistor HS with threshold voltage Vth1.

Voltage Vth1 is, for example, determined, for a maximum value of the current in inductor LpHS at the beginning of each switching to the conductive state of transistor HS, by the threshold value of the drain-source resistance of transistor HS above which the drain-source resistance of transistor HS is considered as increasing, that is, by the threshold value of the drain-source resistance of transistor HS above which, during a switching to the non-conductive state of transistor HS, the latter is considered to be in the third phase of the switching. For example, voltage Vth1 is substantially equal to Imax*10*Rtarget, where Imax is the maximum value expected for the current in inductor LpHS at the beginning of a switching to the non-conductive state of transistor HS, and Rtarget is the threshold value of the drain-source resistance of transistor HS.

As an example, COMP1 comparator has an input, for example non-inverting (+), connected to the input 202 of circuit DET1, an input, for example inverting (−), coupled to the input 204 of circuit DET1 and an output connected to the output 206 of circuit DET1 and configured to deliver signal sig1. For example, the input of comparator COMP1, which is coupled to the drain of transistor HS, is coupled to the input 204 of circuit DET1 by a voltage generator capable of applying a voltage difference Vth1 between input 204 and the input of comparator COMP1.

FIG. 6 shows a detailed example embodiment of the circuit DET2 of the device 2 of FIGS. 3 and 4.

In this example, circuit DET2 comprises a comparator COMP2. Comparator COMP2 is here configured to compare voltage 114 with a threshold voltage Vth2. As an example, voltage Vth2 is the voltage below which, during a switching to the non-conductive state of transistor HS, the voltage at node 114 is considered as being sufficiently close to the zero value. In other words, comparator COMP2 is configured to compare the voltage at node 114 with the voltage at pad 108 increased by threshold voltage Vth2.

As an example, comparator COMP2 has an input, for example inverting (−), connected to the input 210 of circuit DET2, an input, for example non-inverting (+), coupled to the input 212 of circuit DET2, and an output connected to the output 208 of circuit DET2 and configured to deliver signal sig2. As an example, the input of comparator COMP2, which is coupled to pad 108, is coupled to the input 212 of circuit DET2 by a voltage generator capable of applying a voltage difference Vth2 between input 212 and the input of comparator DET2.

FIG. 7 shows a detailed example embodiment of the circuit DET3 of the device 2 of FIG. 4.

Circuit DET3 comprises a PMOS transistor HS-mirror mirror-assembled with transistor HS. In other words, transistor HS-mirror has its gate connected to the gate of transistor HS (input 216 of circuit DET3), its source connected to the source of transistor HS, and thus to pad 102 (input 218 of circuit DET3), and its drain biased by a constant current source or by a resistor R.

In the example of FIG. 7, the drain of transistor HS-mirror is biased by resistor R, the latter being connected between the drain of transistor HS-mirror and pad 108 (input 220 of circuit DET3).

Circuit DET3 also comprises a comparator COMP3. Comparator COMP3 is configured to compare the drain voltage of transistor HS-mirror with a threshold voltage Vth3.

Indeed, in this example, for a given resistance value R, the voltage on the drain of transistor HS-mirror is determined by the current in transistor HS-mirror, and thus in the transistor HS with which transistor HS-mirror is mirror-assembled. Thus, the value of the voltage Vth3 is for example selected so that, when the transistor drain voltage is lower than voltage Vth3, this means that the current in transistor HS-mirror is zero or close to zero, and thus that transistor HS-mirror is in the non-conductive state, transistor HS then also being in the non-conductive state due to the fact that transistors HS and HS-mirror are mirror-assembled.

Detailed examples of embodiments of circuits DET1, DET2, and DET3 have been described hereabove in relation with FIGS. 5, 6, and 7 respectively. However, other implementations of these circuits will occur to those skilled in the art based on the functional indications given hereabove.

Further, although chip 200 has been described for the example where transistor HS, and transistor LS when present, are respectively high-side and low-side switches of a buck DC-DC switched-mode power converter (SMPS), the described embodiments and variants apply to chips 200 where transistor HS, and transistor LS when present, are not high-side and low-side switches of a buck DC-DC SMPS. Indeed, the problem of discharging parasitic inductor LpHS during the switching of the transistor HS coupling pad 102 to node 114 arises in all devices where pad 102 is coupled to a voltage Vin via a wire 106 and where the device drives, by the switching of switch HS, a load coupled to node 114, this being all the truer when the driven load comprises an inductor. This is, for example, the case for a device 2 driving a relay coil or a motor. However, in these relay coil or motor drive applications, the switching frequencies of switch HS are generally lower than in a switched-mode DC-DC converter. Thus, in these applications, it is generally possible to use the same current for controlling switch HS all throughout the first, second, and third phases of each switching to the off state of switch HS, by selecting a value of this drive current sufficiently low to allow the full discharge of parasitic inductor LpHS before the effective switching of switch HS to the off state. This is however not possible in a switched-mode DC-DC converter.

Further, when transistor LS is omitted, those skilled in the art will understand that circuit DET2 is omitted.

The described embodiments and variants are not limited to examples where the load having node 114 coupled thereto comprises an inductor Lext. In other examples, it is possible for the load to comprise no inductor.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove. In particular, regarding circuits HS-CTRL′ and HS-CTRL″, their implementation is within the abilities of those skilled in the art based on the functional indications given hereabove, as well as the implementation of circuits CTRL′ and CTRL″ is within the abilities of those skilled in the art based on the functional indications given hereabove.

1. An integrated circuit chip, comprising:
a first connection pad intended to be coupled to an external supply voltage by a first conductive wire;
a second connection pad intended to be coupled to an external reference voltage by a second conductive wire;
a PMOS transistor coupling the first connection pad to an internal node of the integrated circuit chip intended to be coupled to a load;
a decoupling capacitor coupling the first connection pad to the second connection pad;
a first detection circuit configured to detect an increase, relative to a first threshold, in a drain-source resistance of the PMOS transistor; and
a first control circuit configured, during each switching of the PMOS transistor to the off state, to supply a first current to the gate of the PMOS transistor until the first detection circuit detects said increase in the drain-source resistance, and then to supply a second current lower than the first current.

2. The integrated circuit chip according to claim 1, wherein the integrated circuit chip further comprises a diode coupling the internal node to the second connection pad, the anode of the diode being on the side of the second connection pad.

3. The integrated circuit chip according to claim 1, wherein the internal node is coupled, preferably connected, to a third connection pad of the integrated circuit chip, the third pad being intended to be connected to an external inductor by a third conductive wire, the external inductor forming part of the load.

4. The integrated circuit chip according to claim 1, wherein the integrated circuit chip further comprises a protection circuit against electrostatic discharges coupling the first connection pad to the second connection pad.

5. The integrated circuit chip according to claim 1, wherein the first detection circuit comprises a comparator configured to compare the source voltage of the PMOS transistor with the drain voltage of the PMOS transistor increased by a threshold voltage of the first detection circuit, and to provide a binary signal indicating a result of the comparison.

6. The integrated circuit chip according to claim 1, wherein the integrated circuit chip further comprises a second control circuit configured to supply a first binary signal to the first control circuit, a first binary state of the first binary signal controlling the off state of the PMOS transistor and a second binary state of the first binary signal controlling an on state of the PMOS transistor.

7. The integrated circuit chip according to claim 6, wherein the integrated circuit chip further comprises:
an NMOS transistor coupling the internal node to the second connection pad; and
a third control circuit configured to control the NMOS transistor, the second control circuit being configured to supply a second binary signal to the third control circuit, a first binary state of the second binary signal controlling the off state of the NMOS transistor and a second binary state of the second binary signal controlling an on state of the NMOS transistor.

8. The integrated circuit chip according to claim 7, wherein:
the integrated circuit chip further comprises a second detection circuit configured to detect when a voltage of the internal node is close to a null value by comparison to a second threshold; and
the second control circuit is configured to switch the second binary signal to its second binary state when the second detection circuit detects that the voltage of the internal node is close to the null value.

9. The integrated circuit chip according to claim 8, wherein the second detection circuit comprises a comparator configured to compare the voltage of the internal node with the voltage of the second connection pad increased by a threshold voltage of the second detection circuit, and to provide a binary signal indicating a result of the comparison.

10. The integrated circuit chip according to claim 8, wherein:
the integrated circuit chip further comprises a third detection circuit configured to detect that the PMOS transistor is in the off state; and
the second control circuit is configured to switch the second binary signal to its second binary state when the second detection circuit detects that the voltage of the internal node is close to zero or the third detection circuit detects that the PMOS transistor is in the off state.

11. The integrated circuit chip according to claim 10, wherein the first control circuit is configured to supply the first current when the third detection circuit detects that the PMOS transistor is in the off state or when the first detection circuit does not detect an increase in drain-source resistance, and to supply the second current otherwise.

12. The integrated circuit chip according to claim 1, wherein:
the integrated circuit chip further comprises a further detection circuit configured to detect that the PMOS transistor is in the off state; and
the first control circuit is configured to supply the first current when the further detection circuit detects that the PMOS transistor is in the off state or when the first detection circuit does not detect an increase in drain-source resistance, and to supply the second current otherwise.

13. The integrated circuit chip according to claim 10, wherein the further detection circuit comprises:
an additional PMOS transistor mirror connected with the PMOS transistor and having its drain coupled to the second connection pad by a resistor or constant current source; and
a comparator configured to compare the source voltage of the additional PMOS transistor to a threshold and to provide a binary signal indicating the result of the comparison.

14. The integrated circuit chip according to claim 1, wherein the PMOS transistor is a high-side transistor of a DC-DC switched mode power supply.

15. An electronic device, comprising:
the integrated circuit chip according to claim 1;
a source of the supply voltage disposed outside the integrated circuit chip and coupled to the first connection pad of the integrated circuit chip by the first conductive wire; and
a source of the reference voltage disposed outside the integrated circuit chip and coupled to the second connection pad of the integrated circuit chip by the second conductive wire.
